(19) United States
(12) Patent Application Publication
(10) Pub. No.: US 2018/0076134 A1
(43) Pub. Date: Mar. 15, 2018

(54) INTEGRATED CIRCUIT WITH SHIELDING STRUCTURES

(71) Applicant: Xilinx, Inc., San Jose, CA (US)

(72) Inventors: Jing Jing, San Jose, CA (US); Shuxian Wu, San Jose, CA (US); Xin X. Wu, Fremont, CA (US); Parag Upadhyaya, Los Gatos, CA (US)

(73) Assignee: Xilinx, Inc., San Jose, CA (US)

(21) Appl. No.: 15/267,035

(22) Filed: Sep. 15, 2016

(51) Int. Cl. H01L 23/522; H01L 49/02; H01L 21/768; H01L 23/64

(52) U.S. Cl. CPC H01L 23/5227; H01L 23/645; H01L 21/76895; H01L 28/10

(57) ABSTRACT

A semiconductor device includes an interconnect structure disposed over a semiconductor substrate. The interconnect structure includes a first device disposed in a first portion of the interconnect structure. A first shielding plane including a first conductive material is disposed in a second portion of the interconnect structure over the first portion of the interconnect structure. A second device is disposed in a third portion of the interconnect structure over the second portion of the interconnect structure. An isolation wall including a second conductive material is disposed in the first, second, and third portions of the interconnect structure. The isolation wall is coupled to the first shielding plane, and surrounds the first device, the first shielding plane, and the second device.

### TECHNICAL FIELD

Examples of the present disclosure generally relate to integrated circuits (“ICs”) and, in particular, to an embodiment related to shielding structures for use with an IC.

### BACKGROUND

Semiconductor integrated circuit (IC) technology continues to evolve supporting ever smaller feature sizes. Smaller feature sizes facilitate the creation of smaller devices, thereby allowing a larger number of devices to be implemented within a given area of an IC. As devices are implemented closer to one another and the overall number of devices increases within an IC, the number of electrical interactions between the devices also tends to increase.

One example of an electrical interaction is inductive coupling. Inductive coupling may affect the performance of devices, and in particular, inductors, implemented within an IC. Implementation of inductors within ICs is increasingly important given the high frequency of operations of modern circuits and the need for impedance matching. Many electric interactions such as inductive coupling, however, are difficult to predict and quantify within ICs implemented using modern IC manufacturing technologies.

Accordingly, an improved shielding structure for shielding electrical interactions between devices is desirable.

### SUMMARY

In some embodiments in accordance with the present disclosure, a semiconductor device includes an interconnect structure disposed over a semiconductor substrate. The interconnect structure includes a first device disposed in a first portion of the interconnect structure, a first shielding plane including a first conductive material disposed in a second portion of the interconnect structure over the first portion of the interconnect structure, a second device disposed in a third portion of the interconnect structure over the second portion of the interconnect structure, and an isolation wall including a second conductive material disposed in the first, second, and third portions of the interconnect structure, wherein the isolation wall is coupled to the first shielding plane, and wherein the isolation wall surrounds the first device, the first shielding plane, and the second device.

In some embodiments, the first conductive material and the second conductive material are different.

In some embodiments, the second device is an inductor.

In some embodiments, the inductor includes a coil of a third conductive material different from the first and second conductive materials.

In some embodiments, the first device is disposed in a first conductive layer, the first shielding plane is disposed in a second conductive layer over the first conductive layer, and the second conductive layer is adjacent to the first conductive layer.

In some embodiments, the first shielding plane is disposed in a first conductive layer; the second device is disposed in a second conductive layer over the first conductive layer; and the second conductive layer is adjacent to the first conductive layer.

In some embodiments, the interconnect structure does not include a dummy conductive feature.

In some embodiments, the first shielding plane includes a plurality of fingers, and the isolation wall is coupled to one end of each finger.

In some embodiments, the interconnect structure includes a second shielding plane including a third conductive material disposed in a fourth portion of the interconnect structure over the third portion of the interconnect structure; and a third device disposed in a fifth portion of the interconnect structure over the fourth portion of the interconnect structure.

In some embodiments, the isolation wall surrounds the second shielding plane and the third device.

In some embodiments in accordance with the present disclosure, a method for fabricating a semiconductor device includes forming an interconnect structure disposed over a semiconductor substrate. The forming the interconnect structure includes forming a first device in a first portion of the interconnect structure;

forming a first shielding plane including a first conductive material in a second portion of the interconnect structure over the first portion of the interconnect structure; forming a second device in a third portion of the interconnect structure over the second portion of the interconnect structure; and forming an isolation wall including a second conductive material in the first, second, and third portions of the interconnect structure. The isolation wall is coupled to the first shielding plane, and the isolation wall surrounds the first device, the first shielding plane, and the second device.

Other aspects and features will be evident from reading the following detailed description and accompanying drawings.

### BRIEF DESCRIPTION OF THE DRAWINGS

FIG. 1 is a block diagram illustrating an exemplary architecture for an IC according to some embodiments of the present disclosure.

FIG. 2 is a block diagram illustrating a method to fabricate a semiconductor device according to some embodiments of the present disclosure.

FIG. 3A is a block diagram illustrating a top view of a semiconductor device according to some embodiments of the present disclosure. FIG. 3B is a block diagram illustrating a cross-sectional view of the semiconductor device of FIG. 3A according to some embodiments of the present disclosure.

FIG. 4A is a block diagram illustrating a top view of a semiconductor device according to some embodiments of the present disclosure. FIG. 4B is a block diagram illustrating a cross-sectional view of the semiconductor device of FIG. 4A according to some embodiments of the present disclosure.

FIG. 5A is a block diagram illustrating a top view of a semiconductor device according to some embodiments of the present disclosure. FIG. 5B is a block diagram illustrating a cross-sectional view of the semiconductor device of FIG. 5A according to some embodiments of the present disclosure.

FIG. 6A is a block diagram illustrating a top view of a semiconductor device according to some embodiments of the present disclosure. FIG. 6B is a block diagram illustrating a cross-sectional view of the semiconductor device of FIG. 6A according to some embodiments of the present disclosure.

FIG. 7 is a block diagram illustrating a cross-sectional view of a semiconductor device according to some embodiments of the present disclosure.

FIGS. 8 and 9 illustrate performance comparison between various embodiments according to the present disclosure.

FIG. 10 is a block diagram illustrating a cross-sectional view of a semiconductor device according to some embodiments of the present disclosure.

### DETAILED DESCRIPTION

Various embodiments are described hereinafter with reference to the figures, in which exemplary embodiments are shown. The claimed invention may, however, be embodied in different forms and should not be construed as being limited to the embodiments set forth herein. Like reference numerals refer to like elements throughout. Like elements will, thus, not be described in detail with respect to the description of each figure. It should also be noted that the figures are only intended to facilitate the description of the embodiments. They are not intended as an exhaustive description of the claimed invention or as a limitation on the scope of the claimed invention. In addition, an illustrated embodiment needs not have all the aspects or advantages shown. An aspect or an advantage described in conjunction with a particular embodiment is not necessarily limited to that embodiment and can be practiced in any other embodiments even if not so illustrated, or if not so explicitly described. The features, functions, and advantages may be achieved independently in various embodiments or may be combined in yet other embodiments.

Before describing exemplary embodiments illustratively depicted in the several figures, a general introduction is provided to further understanding. As devices are implemented closer to one another and the overall number of devices increases within an IC, the number of electrical interactions between the devices tends to increase. Such electric interactions may affect the performance of devices. It has been discovered that shielding structures may be used to reduce or eliminate the electric interactions. By using shielding structures according to some embodiments of the present disclosure, circuits that need to be isolated from each other may be vertically stacked over a substrate, thereby greatly saving chip area with little impact to performance. The shielding structures may include a shielding plane disposed in a conductive layer over the substrate. The shielding plane may be coupled to an isolation wall surrounding circuit regions vertically stacked over the substrate. Such shielding structures may isolate electrical interactions between those vertically stacked circuit regions, effectively reduce the eddy current, and help isolate devices (e.g., devices in a particular circuit region) from noise generated by other devices (e.g., devices in other circuit regions over the substrate or devices in the substrate).

With the above general understanding borne in mind, various embodiments for shielding structures are described below. Because one or more of the embodiments are exemplified using a particular type of IC, a detailed description of such an IC is provided below. However, it should be understood that other types of ICs may benefit from one or more of the embodiments described herein.

Programmable logic devices (“PLDs”) are a well-known type of integrated circuit that can be programmed to perform specified logic functions. One type of PLD, the field programmable gate array (“FPGA”), typically includes an array of programmable tiles. These programmable tiles can include, for example, input/output blocks (“IOBs”), configurable logic blocks (“CLBs”), dedicated random access memory blocks (“BRAMs”), multipliers, digital signal processing blocks (“DSPs”), processors, clock managers, delay lock loops (“DLLs”), and so forth. As used herein, “include” and “including” mean including without limitation.

Each programmable tile typically includes both programmable interconnect and programmable logic. The programmable interconnect typically includes a large number of interconnect lines of varying lengths interconnected by programmable interconnect points (“PIPs”). The programmable logic implements the logic of a user design using programmable elements that can include, for example, function generators, registers, arithmetic logic, and so forth.

The programmable interconnect and programmable logic are typically programmed by loading a stream of configuration data into internal configuration memory cells that define how the programmable elements are configured. The configuration data can be read from memory (e.g., from an external PROM) or written into the FPGA by an external device. The collective states of the individual memory cells then determine the function of the FPGA.

Another type of PLD is the Complex Programmable Logic Device (CPLD). A CPLD includes two or more “function blocks” connected together and to input/output (“I/O”) resources by an interconnect switch matrix. Each function block of the CPLD includes a two-level AND/OR structure similar to those used in Programmable Logic Arrays (“PLAs”) and Programmable Array Logic (“PAL”) devices. In CPLDs, configuration data is typically stored on-chip in non-volatile memory. In some CPLDs, configuration data is stored on-chip in non-volatile memory, then downloaded to volatile memory as part of an initial configuration (programming) sequence.

In general, each of these programmable logic devices (“PLDs”), the functionality of the device is controlled by configuration data provided to the device for that purpose. The configuration data can be stored in volatile memory (e.g., static memory cells, as common in FPGAs and some CPLDs), in non-volatile memory (e.g., FLASH memory, as in some CPLDs), or in any other type of memory cell.

Other PLDs are programmed by applying a processing layer, such as a metal layer, that programmably interconnects the various elements on the device. These PLDs are known as mask programmable devices. PLDs can also be implemented in other ways, e.g., using fuse or antifuse technology. The terms “PLD” and “programmable logic device” include but are not limited to these exemplary devices, as well as encompassing devices that are only partially programmable. For example, one type of PLD includes a combination of hard-coded transistor logic and a programmable switch fabric that programmably interconnects the hard-coded transistor logic.

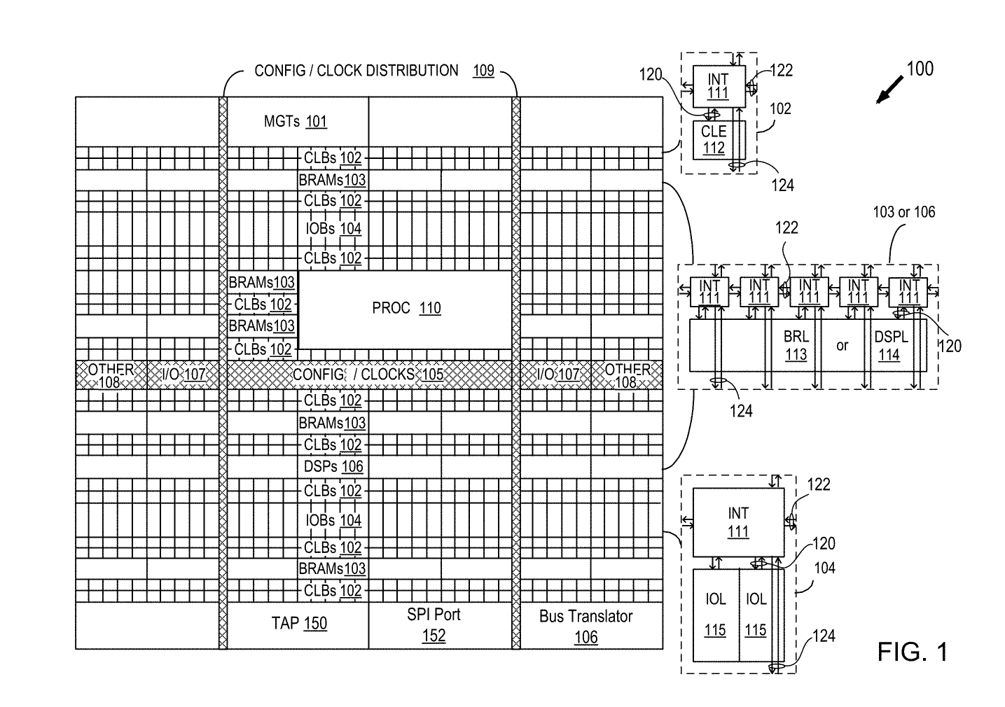

As noted above, advanced FPGAs can include several different types of programmable logic blocks in the array. For example, FIG. 1 illustrates an exemplary FPGA architecture 100. The FPGA architecture 100 includes a large number of different programmable tiles, including multi-gigabit transceivers (“MGTs”) 101, configurable logic blocks (“CLBs”) 102, random access memory blocks (“BRAMs”) 103, input/output blocks (“IOBs”) 104, configuration and clocking logic (“CONFIG/CLOCKS”) 105, digital signal processing blocks (“DSPs”) 106, specialized input/output blocks (“I/O”) 107 (e.g., configuration ports and clock ports), and other programmable logic 108 such as digital clock managers, analog-to-digital converters, system monitoring logic, and so forth. Some FPGAs also include dedicated processor blocks (“PROC”) 110.

In some FPGAs, each programmable tile can include at least one programmable interconnect element (“INT”) 111 having connections to input and output terminals 120 of a programmable logic element within the same tile, as shown by examples included at the top of FIG. 1. Each programmable interconnect element 111 can also include connections to interconnect segments 122 of adjacent programmable interconnect element(s) in the same tile or other tile(s). Each programmable interconnect element 111 can also include connections to interconnect segments 124 of general routing resources between logic blocks (not shown). The general routing resources can include routing channels between logic blocks (not shown) comprising tracks of interconnect segments (e.g., interconnect segments 124) and switch blocks (not shown) for connecting interconnect segments. The interconnect segments of the general routing resources (e.g., interconnect segments 124) can span one or more logic blocks. The programmable interconnect elements 111 taken together with the general routing resources implement a programmable interconnect structure (“programmable interconnect”) for the illustrated FPGA.

In an example implementation, a CLB 102 can include a configurable logic element (“CLE”) 112 that can be programmed to implement user logic plus a single programmable interconnect element (“INT”) 111. A BRAM 103 can include a BRAM logic element (“BRL”) 113 in addition to one or more programmable interconnect elements. Typically, the number of interconnect elements included in a tile depends on the height of the tile. In the pictured example, a BRAM tile has the same height as five CLBs, but other numbers (e.g., four) can also be used. A DSP tile 106 can include a DSP logic element (“DSPL”) 114 in addition to an appropriate number of programmable interconnect elements. An 10B 104 can include, for example, two instances of an input/output logic element (“IOL”) 115 in addition to one instance of the programmable interconnect element 111. As will be clear to those of skill in the art, the actual I/O pads connected, for example, to the I/O logic element 115 typically are not confined to the area of the input/output logic element 115.

In the example of FIG. 1, an area (depicted horizontally) near the center of the die (e.g., formed of regions 105, 107, and 108 shown in FIG. 1) can be used for configuration, clock, and other control logic. Column 109 (depicted vertically) extending from this horizontal area or other columns may be used to distribute the clocks and configuration signals across the breadth of the FPGA.

Some FPGAs utilizing the architecture illustrated in FIG. 1 include additional logic blocks that disrupt the regular columnar structure making up a large part of the FPGA. The additional logic blocks can be programmable blocks and/or dedicated logic. For example, PROC 110 spans several columns of CLBs and BRAMs. PROC 110 can include various components ranging from a single microprocessor to a complete programmable processing system of microprocessor(s), memory controllers, peripherals, and the like.

In one aspect, PROC 110 is implemented as a dedicated circuitry, e.g., as a hard-wired processor, that is fabricated as part of the die that implements the programmable circuitry of the IC. PROC 110 can represent any of a variety of different processor types and/or systems ranging in complexity from an individual processor, e.g., a single core capable of executing program code, to an entire processor system having one or more cores, modules, co-processors, interfaces, or the like.

In another aspect, PROC 110 is omitted from architecture 100, and may be replaced with one or more of the other varieties of the programmable blocks described. Further, such blocks can be utilized to form a “soft processor” in that the various blocks of programmable circuitry can be used to form a processor that can execute program code, as is the case with PROC 110.

The phrase “programmable circuitry” can refer to programmable circuit elements within an IC, e.g., the various programmable or configurable circuit blocks or tiles described herein, as well as the interconnect circuitry that selectively couples the various circuit blocks, tiles, and/or elements according to configuration data that is loaded into the IC. For example, portions shown in FIG. 1 that are external to PROC 110 such as CLBs 102 and BRAMs 103 can be considered programmable circuitry of the IC.

In some embodiments, the functionality and connectivity of programmable circuitry are not established until configuration data is loaded into the IC. A set of configuration data can be used to program programmable circuitry of an IC such as an FPGA. The configuration data is, in some cases, referred to as a “configuration bitstream.” In general, programmable circuitry is not operational or functional without first loading a configuration bitstream into the IC. The configuration bitstream effectively implements or instantiates a particular circuit design within the programmable circuitry. The circuit design specifies, for example, functional aspects of the programmable circuit blocks and physical connectivity among the various programmable circuit blocks.

In some embodiments, circuitry that is “hardwired” or “hardened,” i.e., not programmable, is manufactured as part of the IC. Unlike programmable circuitry, hardwired circuitry or circuit blocks are not implemented after the manufacture of the IC through the loading of a configuration bitstream. Hardwired circuitry is generally considered to have dedicated circuit blocks and interconnects, for example, that are functional without first loading a configuration bitstream into the IC, e.g., PROC 110.

In some instances, hardwired circuitry can have one or more operational modes that can be set or selected according to register settings or values stored in one or more memory elements within the IC. The operational modes can be set, for example, through the loading of a configuration bitstream into the IC. Despite this ability, hardwired circuitry is not considered programmable circuitry as the hardwired circuitry is operable and has a particular function when manufactured as part of the IC.

FIG. 1 is intended to illustrate an exemplary architecture that can be used to implement an IC that includes programmable circuitry, e.g., a programmable fabric. For example, the numbers of logic blocks in a row, the relative width of the rows, the number and order of rows, the types of logic blocks included in the rows, the relative sizes of the logic blocks, and the interconnect/logic implementations included at the top of FIG. 1 are purely exemplary. For example, in an actual IC, more than one adjacent row of CLBs is typically included wherever the CLBs appear, to facilitate the efficient implementation of user logic, but the number of adjacent CLB rows varies with the overall size of the IC. Moreover, the FPGA of FIG. 1 illustrates one example of a programmable IC that can employ examples of the interconnect circuits described herein. The interconnect circuits described herein can be used in other types of programmable ICs, such as CPLDs or any type of programmable IC having a programmable interconnect structure for selectively coupling logic elements.

It is noted that the IC that may incorporate the semiconductor devices including the shielding structures is not limited to the exemplary IC depicted in FIG. 1, and that IC having other configurations, or other types of IC, may also include the shielding structures. One or more semiconductor devices having the shielding structures according to one or more embodiments may be incorporated in any of several functional blocks of the FPGA, such as a multi-gigabit transceivers 101.

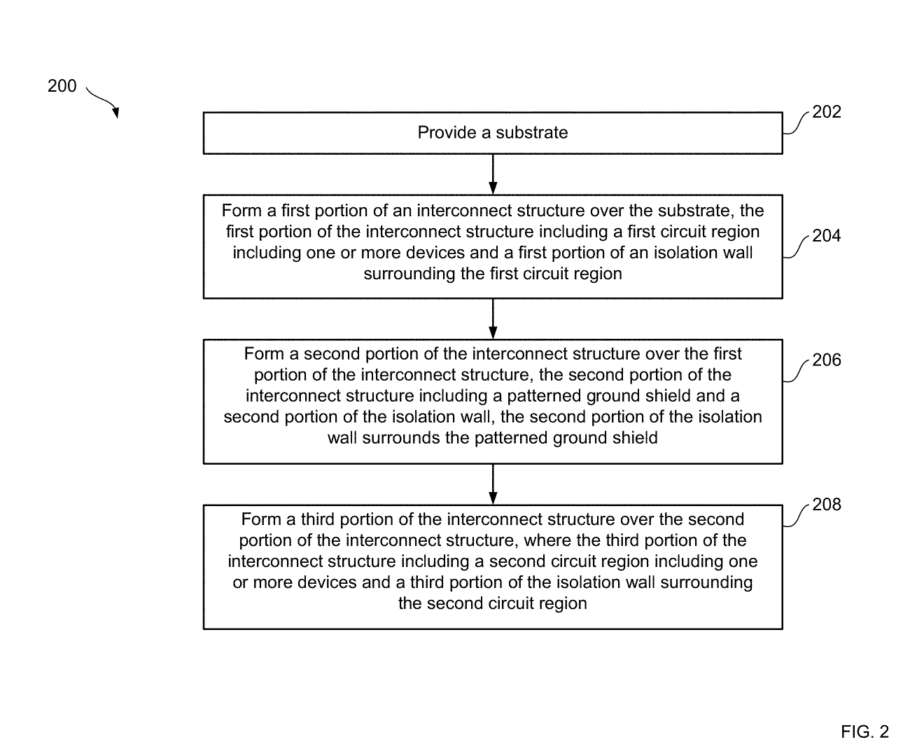

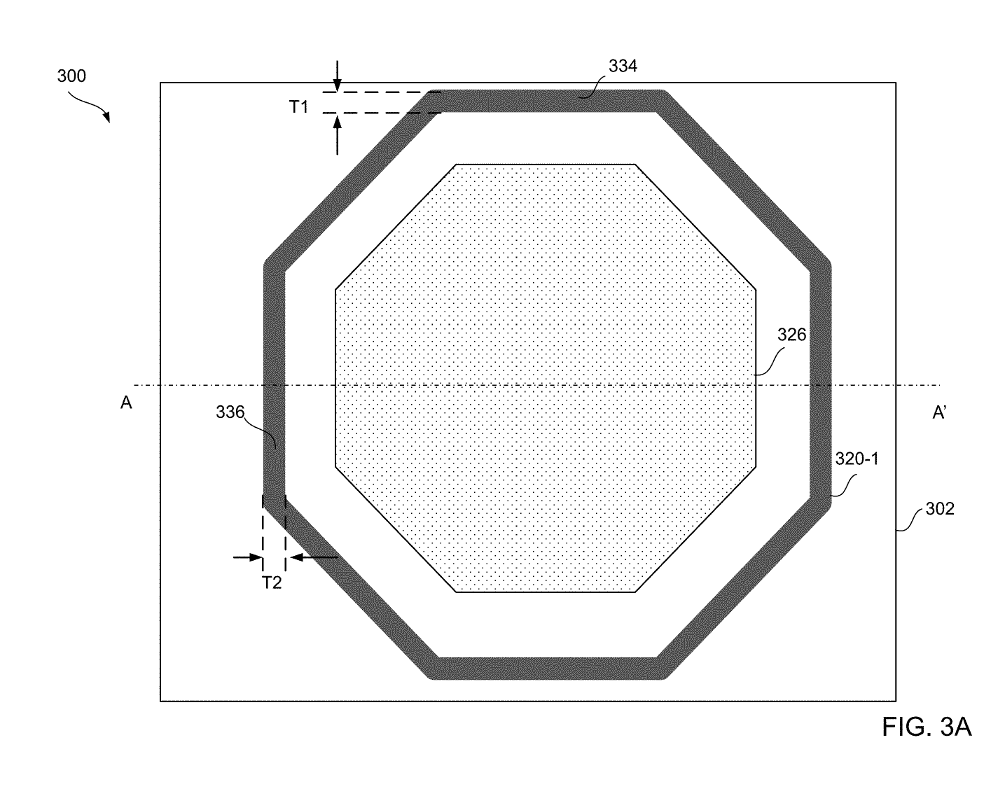

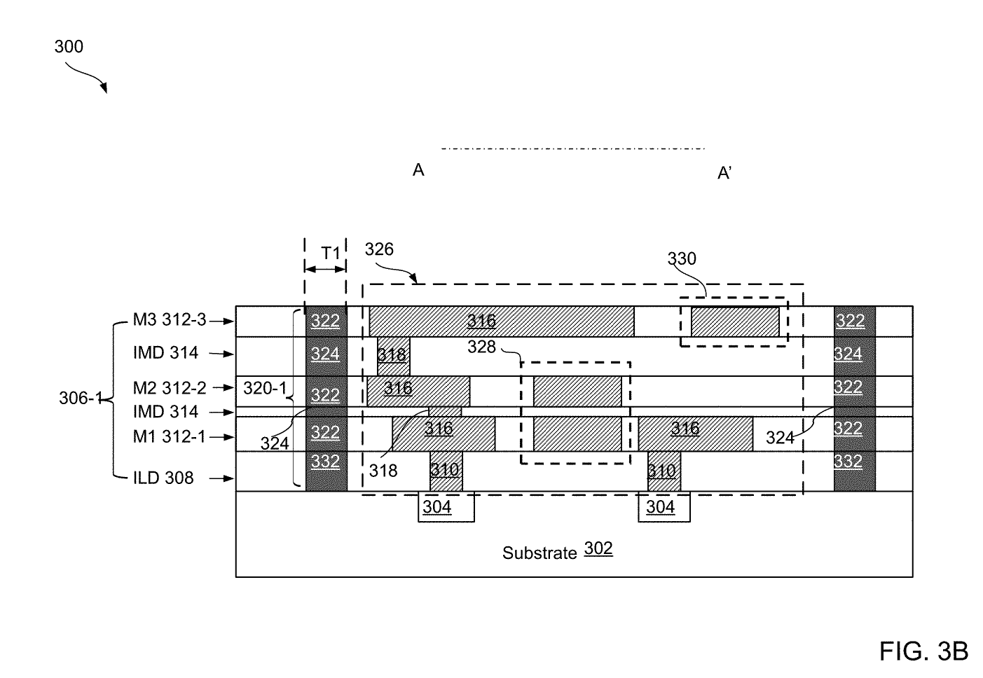

Referring to FIG. 2, illustrated is a flow chart of a method 200 of fabricating a semiconductor device according to various aspects of the present disclosure. Referring to FIGS. 2, 3A, and 3B, the method 200 begins with block 202, in which a semiconductor substrate including electronic devices formed therein. Referring to the examples of FIGS. 3A and 3B, in an embodiment of block 202, a device 300 is provided. The device 300 includes a substrate 302 and a plurality of semiconductor devices 304 formed in or on the substrate 302.

The substrate 302 may be a semiconductor substrate such as a silicon substrate. The substrate 302 may include various doping configurations depending on design requirements. The substrate 302 may also include other semiconductors such as germanium, silicon carbide (SiC), silicon germanium (SiGe), or diamond. Alternatively, the substrate may include a compound semiconductor and/or an alloy semiconductor. Further, the substrate may optionally include an epitaxial layer (epi-layer), may be strained for performance enhancement, may include a silicon-on-insulator (SOI) structure, and/or have other suitable enhancement features.

The semiconductor devices 304 formed in or on the substrate 302 may include active components such as Field Effect Transistors (FETs), Bipolar Junction Transistors (BJTs), and diodes, or passive components such as resistors, capacitors, and transformers. The device 300 may include millions or billions of these semiconductor devices 304, but only a few are shown in FIGS. 3A and 3B for the sake of simplicity.

In some embodiments, isolation features are formed in the substrate 302. The isolation features may define and isolate active regions for various semiconductor devices 304. In some embodiments, isolation features include shallow trench isolation (STI) features. The STI features contain a dielectric material, which may be silicon oxide, silicon nitride, silicon oxy-nitride, fluoride-doped silicate (FSG), and/or a low-k dielectric material. The STI features may be formed by etching trenches in the substrate 302 thereafter filling the trenches with the dielectric material. In some embodiments, deep trench isolation (DTI) features may also be formed in place of or in combination with the STI features as the isolation features.

Referring to FIGS. 2, 3A, and 3B, the method 200 proceeds to block 204, where a first portion of an interconnect structure 306-1 is formed over the substrate 302. The first portion of the interconnect structure 306-1 may include a first portion of an isolation wall 320-1. In some embodiments, the first portion of the isolation wall 320-1 partially or completely surrounds a circuit region 326 disposed in the first portion of the interconnect structure 306-1.

Referring to FIGS. 3A and 3B, the first portion of the interconnect structure 306-1 includes an interlayer dielectric (ILD) layer 308 formed over the substrate 302. The ILD layer 308 may include silicon oxide, silicon oxynitride, a low-k dielectric material, or other suitable materials. The ILD layer 308 may be formed by chemical vapor deposition (CVD), high density plasma CVD (HDP-CVD), physical vapor deposition (PVD) or other suitable technique. The semiconductor device 300 may include a plurality of contacts 310 formed in the ILD layer 308. The contacts 310 may be formed by patterning and etching the ILD layer 308 to form trenches. The trenches may be filled by depositing a conductive material (e.g., tungsten or other metallic materials), thereby forming the contacts 310. The contacts 310 may provide connections to the various semiconductor devices 304 formed in the substrate 302. In some embodiments, the contacts 310 may include contacts providing connections between the first portion of an isolation wall 320-1 and the substrate 302, and those contacts may be referred to as isolation wall contacts 332. In some examples, the isolation wall contacts 332 include a conductive material that is the same as a contact 310 providing connection to the semiconductor devices 304. In some examples, the isolation wall contacts 332 include a conductive material that is different from a conductive material of the contact 310 providing connection to the semiconductor devices 304.

In some embodiments, the first portion of the interconnect structure 306-1 includes a plurality of metal layers 312, which are referred to as metal layers 312-1 (M1), 312-2 (M2), and 312-3 (M3). The metal layers 312-1 (M1), 312-2 (M2), and 312-3 (M3) may also be referred to as conductive layers 312-1 (M1), 312-2 (M2), and 312-3 (M3) respectively. The metal layers 312 may include metal lines 316 formed of conductive materials such as aluminum, copper, aluminum/silicon/copper alloy, titanium, titanium nitride, tantalum, tantalum nitride, tungsten, polysilicon, other suitable conductive materials, or combinations thereof.

The first portion of the interconnect structure 306-1 may include inter-metal dielectric (IMD) layers 314 insulating the metal layers 312 from each other. In some embodiments, the IMD layers 314 at various levels of the first portion of the interconnect structure 306-1 may include different dielectric materials. IMD layers 314 with low-k (LK), extreme low-k (ELK), and/or extra low-k (XLK) materials may enhance circuit performance. The material classification may be based upon the value of a dielectric constant k. For example, LK materials may refer to those materials with a k value less than approximately 3.5, and preferably less than approximately 3.0. The ELK materials may refer to those materials with a k value less than approximately 2.9, and preferably less than approximately 2.6. The XLK materials may refer to those materials which typically have a k value less than approximately 2.4. Those classifications are mere examples and that other classifications based on the dielectric constant of the material may be utilized as well. The dielectric materials may comprise silicon nitride, silicon oxynitride, spin-on glass (SOG), undoped silicate glass (USG), fluorinated silica glass (FSG), carbon doped silicon oxide (e.g., SiCOH), carbon-containing material, polyimide, other proper porous polymeric materials, other suitable dielectric materials, and/or combinations thereof. In some embodiments, the IMD layers 314 include metal vias 318 connecting metal lines 316 in different metal layers. The IMD layers 314 may be formed by techniques including spin-on, CVD, PVD, or atomic layer deposition (ALD).

In some embodiments, the metal layers 312 and the IMD layers 314 may be formed in an integrated process such as a damascene process or lithography/plasma etching process. In the example of FIGS. 3A and 3B, the bottommost metal layer 312-1 (M1) includes metal lines 316 that are coupled to the contacts 310 for connecting to the semiconductor devices 304 formed in the substrate 302.

In some embodiments, the first portion of the interconnect structure 306-1 includes a circuit region 326. The circuit region 326 may include various devices including for example, transistors, diodes, capacitors, resistors, transformers, transmission lines, any other suitable devices, and/or a combination thereof. In some examples, the circuit region 326 includes a capacitor 328 (e.g., a metal-insulator-metal (MIM) capacitor), which includes two capacitor plates located in metal layers 312-1 and 312-2 respectively, and a portion of an IMD layer 314 located between those two capacitor plates. In such an example, the particular IMD layer 314 implementing the capacitor 328 may have a thickness that is smaller than the thickness of other IMD layers. That particular IMD layer 314 may have a high k value (e.g., greater than 7) that is different from the k value of other IMD layers 314. In some examples, the circuit region 326 includes a device 330 (e.g., a resistor) and transmission lines formed using various metal lines 316 and metal vias 318. In some examples, the circuit region 326 includes decoupling capacitor array. In some examples, the circuit region 326 includes capacitor-tuning circuits including finger capacitor and varactor arrays.

In some embodiments, the first portion of the interconnect structure 306-1 includes a first portion of an isolation wall 320-1 formed by isolation wall conductive lines 322 (also referred to as isolation wall metal lines 322) in the metal layers 312 and isolation wall conductive vias 324 in the IMD layers 314. Adjacent isolation wall conductive lines 322 in adjacent metal layers (e.g., in adjacent metal layers 312-1 and 312-2) may be coupled together using one or more isolation wall conductive vias 324 disposed in an IMD layer 314 between the adjacent metal layers. In some embodiments, isolation wall conductive lines 322 and isolation wall conductive vias 324 include a conductive material that is the same as the isolation wall contacts 332. In some embodiments, isolation wall conductive lines 322, isolation wall conductive vias 324, and isolation wall contacts 332 may include conductive materials different from each other.

In some embodiments, the first portion of the isolation wall 320-1 includes isolation wall contacts 332 in the ILD layer 308, and couples to the substrate 302 through the isolation wall contacts 332. In some embodiments, bottom surfaces of the isolation wall contacts 332 physically contact silicon top surfaces of the substrate 302. In some embodiments, bottom surfaces of the isolation wall physically contact a P-type diffusion material disposed within the substrate 302.

As illustrated in the examples of FIGS. 3A and 3B, shapes, sizes, and locations of the circuit region 326 and the isolation wall 320 may be designed to improve circuit performance (e.g., to improve chip area utilization, to reduce coupling effect with other devices located in other circuit regions or in the substrate). The circuit region 326 and the isolation wall 320 may be of various shapes (e.g., circles, squares, rectangles, octagons). The shapes of the circuit region 326 and the isolation wall 320 may be determined based on circuit performance requirements and/or design rule limitations. In some embodiments, the thickness of the isolation wall may be tuned to adjust the resistance of the isolation wall (e.g., reducing the resistance by increasing the thickness of the isolation wall). In some examples, portions (e.g., sidewalls) of the isolation wall 320 may have different thicknesses determined based on resistance requirements and the available space. In the example illustrated in FIG. 3A, portions 334 and 336 of the first portion of the isolation wall 320-1 have thicknesses T1 and T2 respectively, where T1 and T2 are different.

In some embodiments, as illustrated in FIG. 3B, the circuit region 326 vertically extends from metal layer 312-1 to metal layer 312-3. In other words, the circuit region 326 may include devices disposed in a top most metal layer of the first portion of the interconnect structure 306-1 (e.g., metal layer 312-3) and devices disposed in a bottom most metal layer of the first portion of the interconnect structure 306-1 (e.g., metal layer 312-1). Alternatively, in some embodiments, the circuit region 326 includes devices disposed in only some of the metal layers of the first portion of the interconnect structure 306-1. In some examples, devices of the circuit region 326 are disposed in metal layers 312-1 and 312-2, but not in metal layer 312-3. In some examples, devices of the circuit region 326 are disposed in metal layers 312-2 and 312-3, but not in metal layer 312-1.

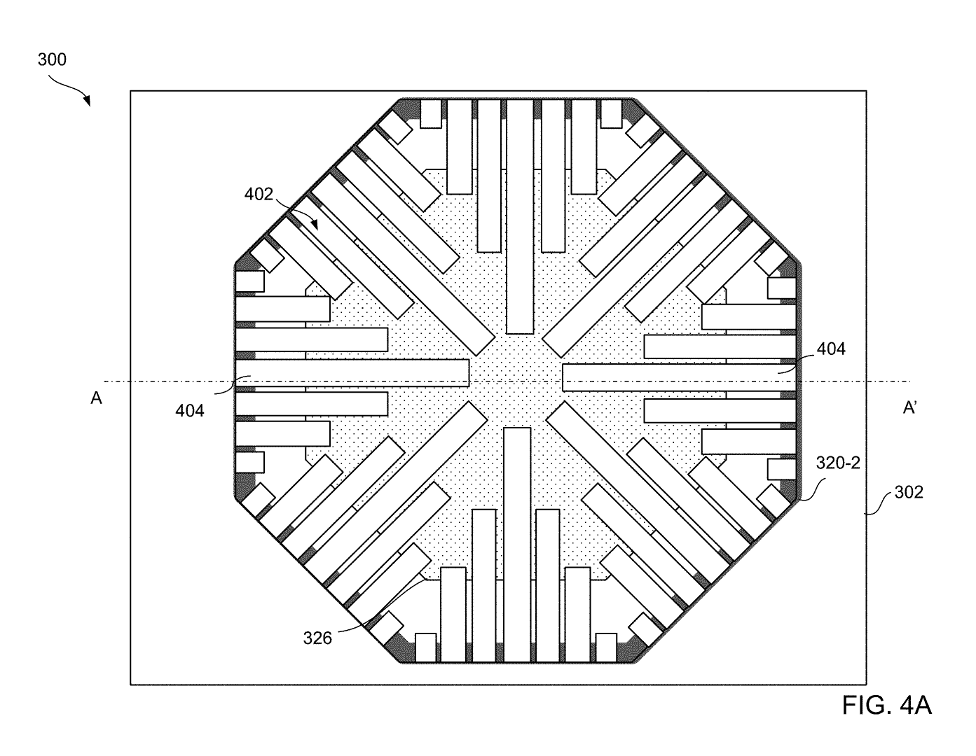

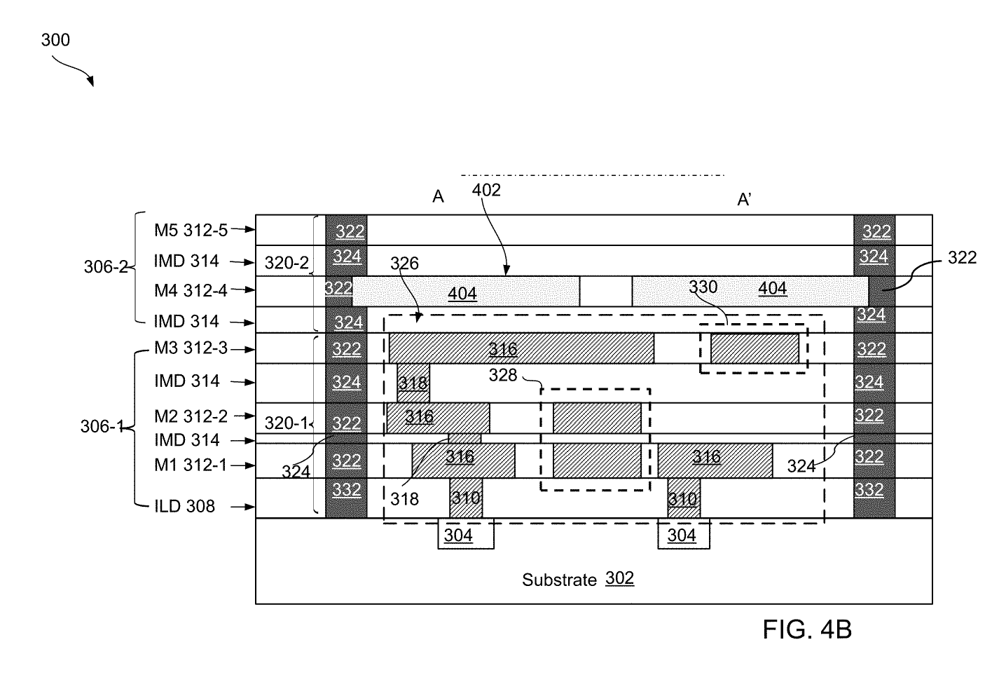

Referring to FIGS. 2, 4A, and 4B, the method 200 proceeds to block 206, where a second portion of the interconnect structure 306-2 is formed over the first portion of the interconnect structure 306-1. The second portion of the interconnect structure 306-2 may include a shielding plane 402 implemented in one or more metal layers of the second portion of the interconnect structure 306-2. In various embodiments, the shielding plane 402 may have a pattern (e.g., a pattern designed based on the device(s) disposed over and/or below the shielding plane 402), and may also be referred to as a patterned ground shield 402. The second portion of the interconnect structure 306-2 may further include a second portion of the isolation wall 320-2 partially or completely surrounding the patterned ground shield 402.

Referring to FIGS. 4A and 4B, the second portion of the interconnect structure 306-2 includes metal layers 312-4 (M4) and 312-5 (M5) and IMD layers 314 disposed between the metal layers 312. A patterned ground shield 402 is formed in the metal layer 312-4.

Referring to FIG. 4A, illustrated is a top view of the device 300 after the patterned ground shield 402 formed in the metal layer 312-4. In various embodiments, a patterned ground shield 402 may include groups of a plurality of parallel, conductive strips (fingers) 404. In embodiments where an inductor structure is disposed over the patterned ground shield 402, the patterned ground shield 402 may be configured so as to not impede the magnetic field surrounding the coil(s) of the inductor structure. In some embodiments, the strips 404 of the patterned ground shield 402 may be coupled together at the outer perimeter of the patterned ground shield 402. In some embodiments, a second portion of the isolation wall 320-2 is used to couple the strips 404 together (e.g., using isolation wall metal lines 322 in the conductive layer M4). The patterned ground shield 402 and an isolation wall 320 may isolate the electric field generated by current flow through devices disposed over the patterned ground shield 402 (e.g., an inductor in a circuit region over the patterned ground shield 402) from devices in a circuit region 326 disposed between the patterned ground shield 402 and the substrate 302.

In various embodiments, the patterned ground shield 402 may be implemented in any of the metal layers of the second portion of the interconnect structure 306-2. In some embodiments, the patterned ground shield 402 may be implemented in one or more metal layers of the second portion of the interconnect structure 306-2. The metal layer(s) implementing the patterned ground shield 402 may be referred to as PGS metal layer(s). In the example of FIG. 4B, the second portion of the interconnect structure 306-2 includes one or more metal layers (e.g., metal layer 312-5) over the PGS metal layer 312-4, but no metal layers below the PGS metal layer 312-4. In furtherance of the example of FIG. 4B, the PGS metal layer is adjacent to a top-most metal layer 312-3 of the circuit region 326. In some embodiments, by implementing the patterned ground shield 402 in a metal layer adjacent to a top-most metal layer of the circuit region 326, more distance between the patterned ground shield 402 and a circuit region disposed over the patterned ground shield 402 may be achieved to improve circuit performance.

In various embodiments, the patterned ground shield 402 include conductive materials such as aluminum, copper, aluminum/silicon/copper alloy, titanium, titanium nitride, tantalum, tantalum nitride, tungsten, polysilicon, other suitable conductive materials, or combinations thereof.

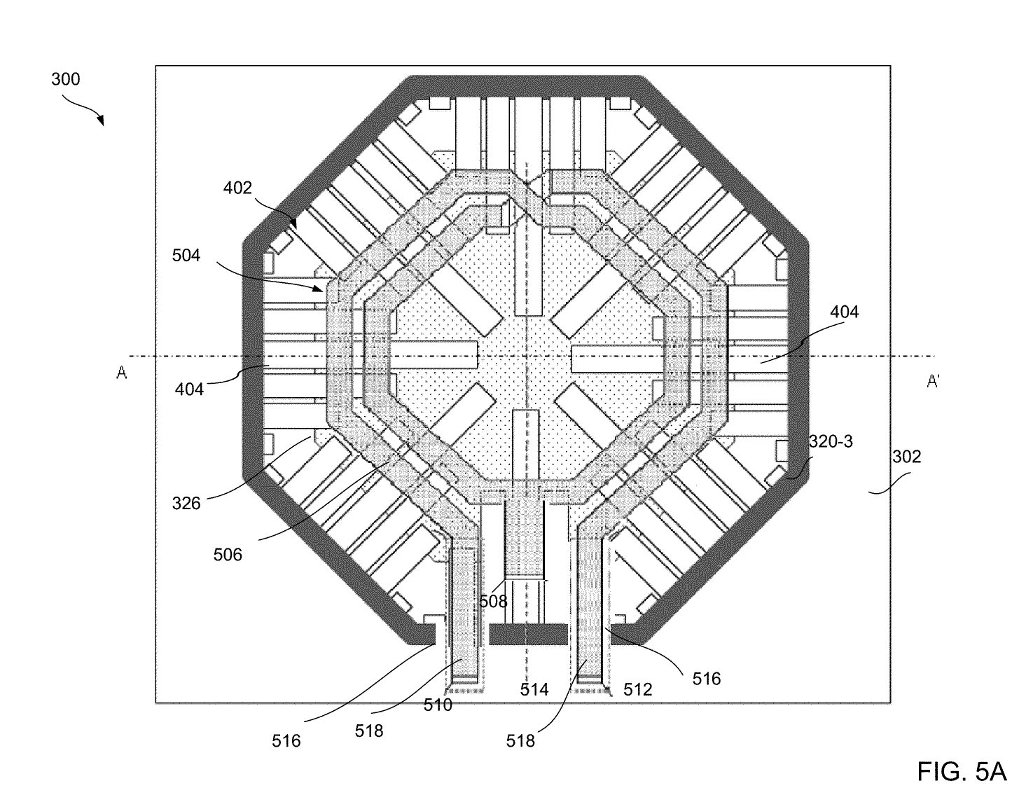

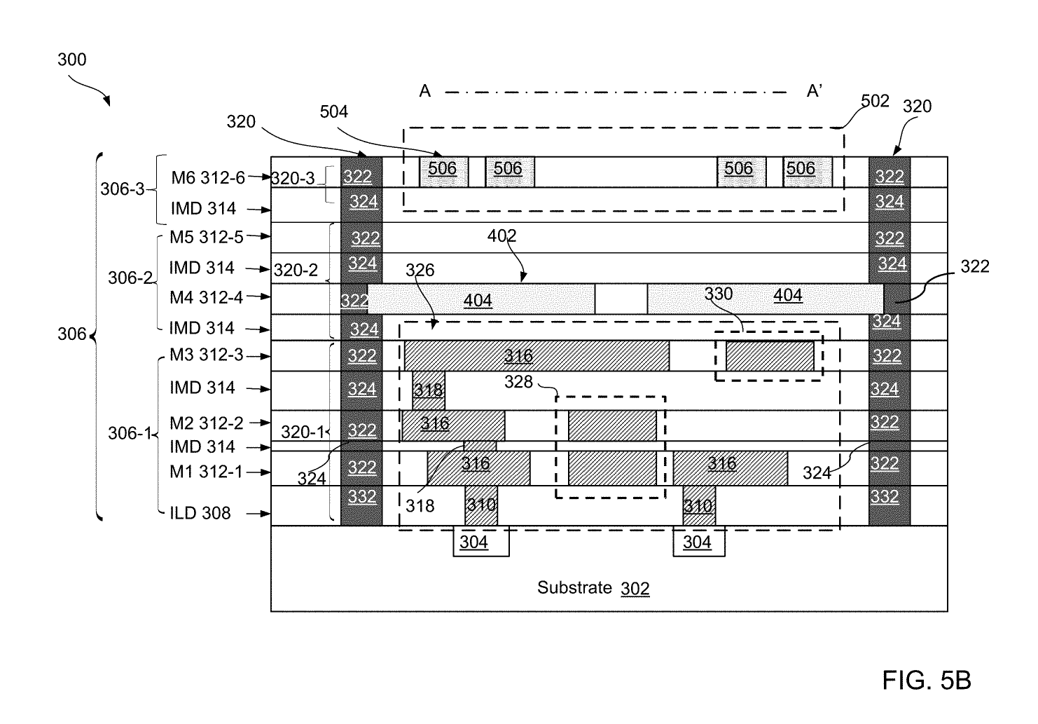

Referring to FIGS. 2, 5A and 5B, the method 200 proceeds to block 208, where a third portion of the interconnect structure 306-3 is formed over the second portion of the interconnect structure 306-2. The third portion of the interconnect structure 306-3 may include a circuit region 502, and a third portion of the isolation wall 320-3 surrounding the circuit region 502.

Referring to FIGS. 5A and 5B, the third portion of the interconnect structure 306-3 includes metal layer 312-6 (M6), and IMD 314 disposed between the metal layers 312-5 (M5) and 312-6. The third portion of the interconnect structure 306-3 includes circuit region 502 implemented using the metal layer 312-6 and/or IMD 314. The circuit region 502 may include various devices including for example, transistors, diodes, inductors, capacitors, resistors, transformers, transmission lines, any other suitable devices, and/or a combination thereof. In the particular examples of FIGS. 5A and 5B, the devices of the circuit region 502 include an inductor 504. The inductor 504 includes a coil 506 implemented in the metal layer 312-6 and a plurality of terminals including for example, a center terminal 508, and differential terminals 510 and 512. The coil 506 and terminals 508, 510, and 512 may be coupled together and represent one continuous area of a conductive material. While in the particular example of FIGS. 5A and 5B, the coil 506 and terminals 508, 510, and 512 are implemented using a single metal layer, in some examples, coil 506 and terminals 508, 510, and 512 may be implemented using two or more vertically stacked metal layers. In those examples, adjacent metal layers of coil 506 and terminals 508, 510, and 512 may be coupled together using one or more vias to form one continuous conductive pathway.

In some embodiments, as illustrated in FIG. 5A, coil 506 is symmetrical and has two turns, and a centerline 514 may be determined to substantially symmetrically bisect coil 506. It is noted that the implementation of coil 506 as an octagonal coil is provided for purposes of illustration only and is not intended as a limitation. In various embodiments, coil 506 may be implemented in any of a variety of forms or shapes.

In some embodiments, the third portion of the interconnect structure 306-3 includes a third portion of the isolation wall 320-3 surrounding the circuit region 502. The third portion of the isolation wall 320-3 includes isolation wall metal lines 322 in metal layer 312-6 and isolation wall conductive vias 324 in IMD layer 314 adjacent to the metal layer 312-6. The third portion of the isolation wall 320-3 is coupled to the second portion of the isolation wall 320-2 through isolation wall conductive vias 324. It is noted that while in the example of FIGS. 5A and 5B, the inductor 504 is implemented in a top-most metal layer M6 of the interconnect structure 306, in some embodiments, the inductor 504 may be implemented in one or more metal layers closer to the substrate 302. In those embodiments, one or more metal layers may be disposed over the inductor 504, and the isolation wall 320 may be implemented in those metal layers over the inductor 504. In other words, a portion of the isolation wall 320 may be disposed over the inductor 504.

In some embodiments, the coil 506 includes a conductive material such as aluminum, copper, aluminum/silicon/copper alloy, titanium, titanium nitride, tantalum, tantalum nitride, tungsten, polysilicon, other suitable conductive materials, or combinations thereof. In some examples, the conductive material of the coil 506 is different from the conductive materials of the patterned ground shield 402 and the isolation wall 320. For example, the conductive material of the coil 506 may have a conductivity higher than those of the conductive materials of the patterned ground shield 402 and the isolation wall 320.

In some embodiments, the patterned ground shield 402 has a pattern that is designed based on the devices disposed over and/or underneath the patterned ground shield 402 to reduce eddy current and isolate electrical interactions between devices disposed on opposite sides of the patterned ground shield 402. In the example of FIGS. 5A and 5B, fingers 404 of the patterned ground shield 402 are arranged in a pattern based on the inductor 504 disposed over patterned ground shield 402. For example, each finger 404 is oriented substantially perpendicular to the direction of current within segments of the coil 506. Fingers 404 crossing the same linear segment of the coil 506 may be substantially parallel, and be separated from one another by a same predetermined spacing.

In some embodiments, the interconnect structure 306 may include dummy conductive features (e.g., dummy conductive lines in the metal layers 312, and/or dummy conductive vias in the IMD layers 314) that are not electrically connected to any functional circuit. Those dummy conductive features may be used, for example, to meet a metal density requirement (e.g., for better polishing effect).

Alternatively, as illustrated in FIGS. 5A and 5B, in some embodiments, the interconnect structure 306 does not include any dummy conductive features. In those embodiments, the metal density requirement is satisfied by patterned ground shield 402 and/or devices located in the circuit regions 326 and 502.

In some embodiments, as illustrated in FIGS. 5A and 5B, the portion of isolation wall 320 through which each of legs 518 of coil 506 crosses can be at least partially discontinuous. More particularly, isolation wall metal line 322 in conductive layer M6 may have a discontinuity or a gap 516 so as to allow each of the legs 518 of coil 506 to cross isolation wall 320. It is noted that isolation wall metal line 322 in lower conductive layers may not have a discontinuity or gap.

In some embodiments, routings are formed to connect the circuits inside the isolation wall 320 to circuits outside of the isolation wall 320. In such embodiments, the isolation wall 320 may include openings by removing portions of the isolation wall 320 in one or more metal layers. The routings may pass through the isolation wall 320 using these openings, where the routings are isolated from the isolation wall 320 by dielectric materials.

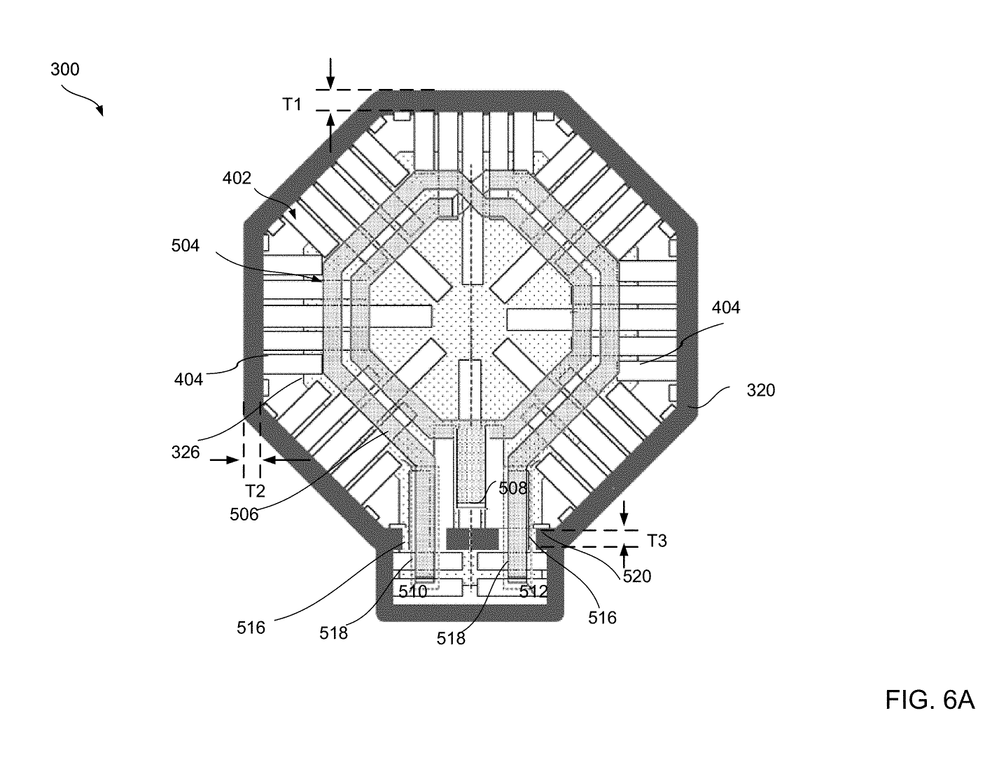

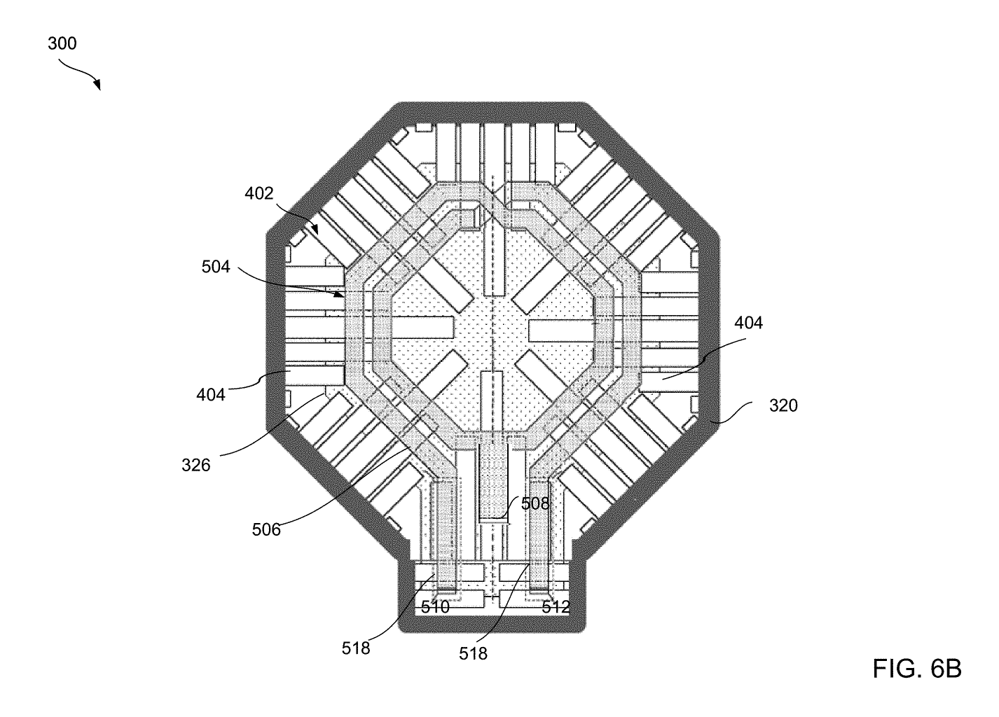

Referring to FIGS. 6A and 6B, different configurations of the isolation walls are illustrated. In the examples of FIGS. 6A and 6B, the isolation wall 320 encloses the legs 518 of the inductor 504. In the example of FIG. 6A, the isolation wall 320 includes a wall 520 to separate the inductor coil region and the inductor leg region, which may isolate the circuits placed in the leg region and circuits placed in the coil region. In an example, the wall 520 has a thickness T3 less than the thicknesses (e.g., thicknesses T1 and T2) of other portions of the isolation wall 320. In the example of FIG. 6B, the isolation wall 320 does not have a sidewall separating the inductor coil region and the inductor leg.

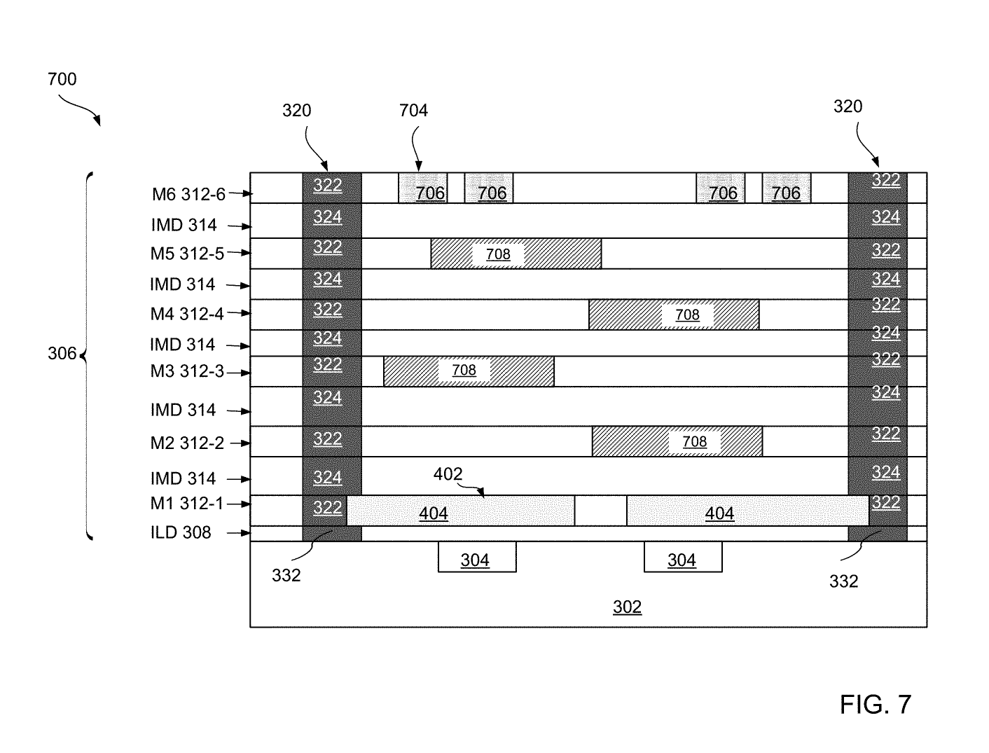

Referring to FIG. 7, in some embodiments, the interconnect structure 306 of a device does not include a circuit region including devices disposed between a top surface of a substrate and a patterned ground shield. In the example of FIG. 7, a device 700 includes an interconnect structure 306. The interconnect structure 306 includes an inductor 704 including a coil 706 disposed in a top-most metal layer M6. The inductor 704 may be substantially similar to the inductor 504 of FIGS. 5A and 5B. The interconnect structure 306 includes a shielding structure including a patterned ground shield 402 disposed in a bottom-most metal layer M1 and an isolation wall 320 coupled to the patterned ground shield 402. The patterned ground shield 402 and the isolation wall 320 may be substantially similar to the patterned ground shield 402 and isolation wall 320 of FIG. 5B respectively, except that the patterned ground shield 402 is located in the metal layer M1. As such, the interconnect structure 306 does not include a circuit region having devices between a top surface of the substrate 302 and the patterned ground shield 402.

In some embodiments, the interconnect structure 306 may include dummy metal features 708 (e.g., dummy metal lines in the metal layers 312, and/or dummy metal vias in the IMD layers 314) that are not electrically connected to any functional circuit. Those dummy metal features may be used, for example, to meet a metal density requirement (e.g., for better polishing effect).

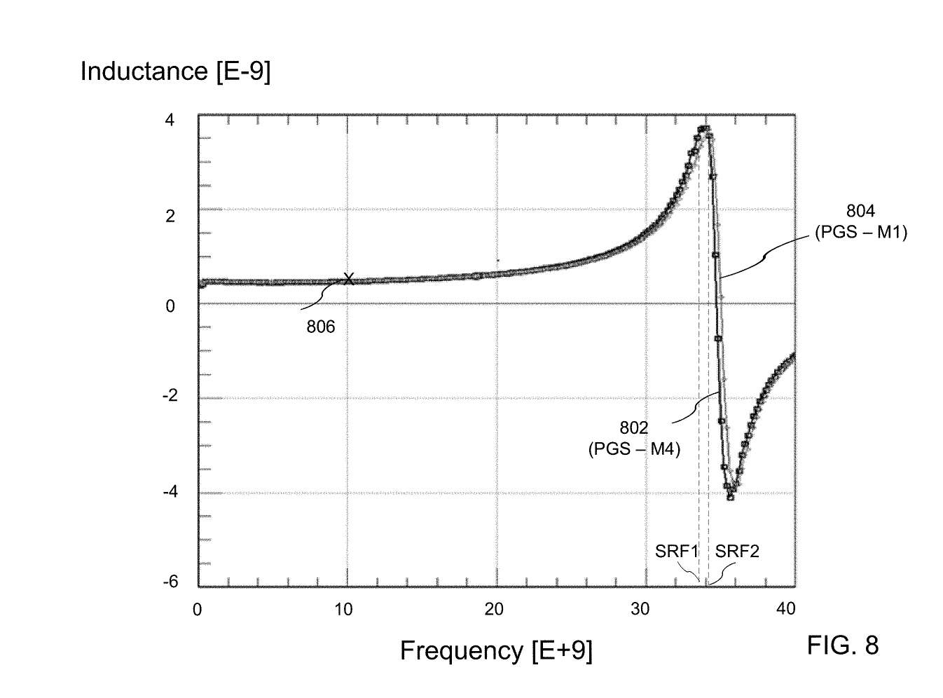

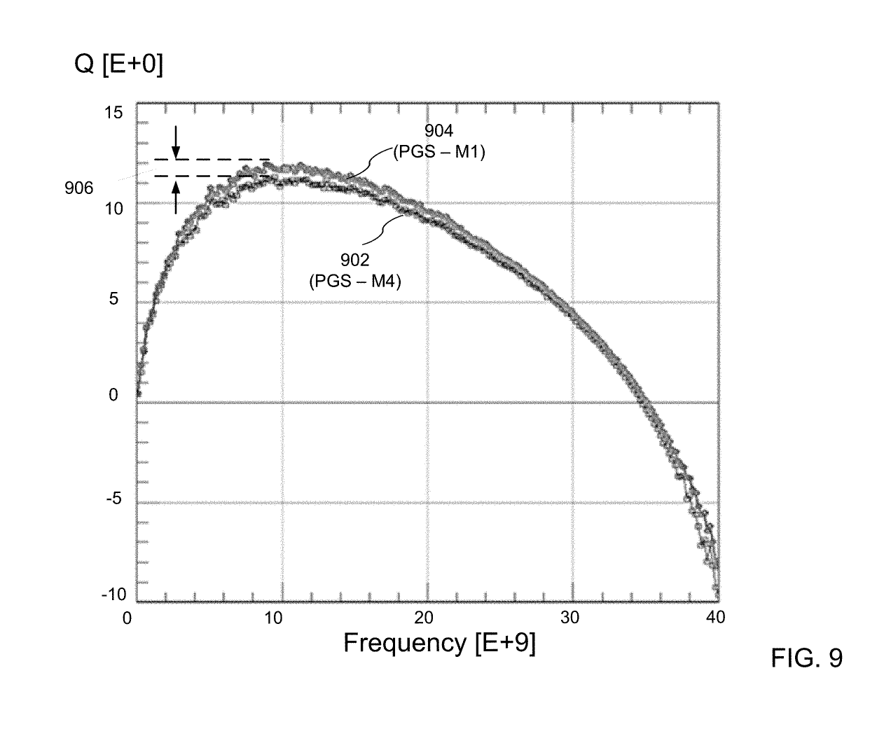

Referring to FIGS. 8 and 9, the performances of inductors with different configurations of patterned ground shields and isolation walls are compared. As shown by the comparison, devices may be disposed underneath an inductor to save chip area without causing much degradation to the inductor Q of the inductor. This may be achieved by using shielding and isolation structures including the patterned ground shields and isolation walls as discussed above with reference to. Referring to FIG. 8, illustrated are inductance curves (e.g., inductance against frequency) of inductors implemented according to various embodiments with different configurations (e.g., locations of the PGS, existence (or the lack thereof) the circuit region between a top surface of a substrate and the PGS). Inductance curve 802 corresponds to an inductor 504 of the device 300 of FIGS. 5A and 5B. In the device 300 of FIGS. 5A and 5B, the patterned ground shield is disposed in an intermediate metal layer M4 between a bottom-most metal layer M1 and a top-most metal layer M6 of the interconnect structure 306, and the inductor 504 is implemented in the top-most metal layer M6 of the interconnect structure 306. Inductance curve 804 corresponds to an inductor 704 of the device 700 of FIG. 7, where the patterned ground shield 402 is disposed in a bottom-most metal layer M1 of an interconnect structure 306 over the substrate 302. As such, in the device 700, no devices are disposed between a top surface of the substrate and the patterned ground shield 402. As shown in the example of FIG. 8, the inductance curves 802 and 804 are substantially the same at operation frequencies. For example, for a particular operation frequency less than the self resonance frequencies (SRFs) of curves 802 and 804, the difference between the inductances of curves 802 and 804 is within 0.01% of the inductance of the curve 804. In the examples of FIG. 8, curve 802 has an SRF (also referred to as SRF1) at about 33.82 GHz. Curve 804 has an SRF (also referred to as SRF 2) at about 34.21 GHz. At a frequency (e.g., 10 GHz) that is less than both SRF1 and SRF2, inductances 806 for both curve 804 and 802 are about the same at 491 pH. While in the example of FIG. 8 the difference of inductances may increase slightly for frequencies closer to and/or greater than the SRF1 and SRF2, such difference may not affect circuit performance, because the operating frequencies usually are far less than the SRF. As such, by using a shielding structure including a patterned ground shield coupled to an isolation wall, devices disposed between substrate and the patterned ground shield may have little impact to the inductance of an inductor disposed over the patterned ground shield.

Referring to FIG. 9, illustrated are quality factor Q curves (e.g., quality factor Q against frequency) of inductors implemented according to various embodiments with different configurations (e.g., locations of the PGS, existence (or the lack thereof) the circuit region between a top surface of a substrate and the PGS). Inductance curve 902 corresponds to an inductor 504 of the device 300 of FIGS. 5A and 5B, where the patterned ground shield 402 is disposed in an intermediate metal layer M4 between a bottom-most metal layer M1 and a top-most metal layer M6 of the interconnect structure 306, and the inductor 504 is implemented in the metal layer M6. Inductance curve 904 corresponds to an inductor 704 of the device 700 of FIG. 7, where the patterned ground shield 402 is disposed in a bottom-most metal layer 312-1 (M1) of an interconnect structure 306 over the substrate 302, and the inductor 704 is disposed in a top-most metal layer M6 of the interconnect structure 306. As shown by FIG. 9, the Q values of the inductors 506 and 704 at the same frequency are substantially the same, and a difference 906 between the Q values of the inductors 506 and 704 at a particular frequency is less than about 5% of the Q value of the inductor 704. As such, by using a shielding structure including a patterned ground shield coupled to an isolation wall, devices disposed between substrate and the patterned ground shield may have little impact to the Q of an inductor disposed over the patterned ground shield.

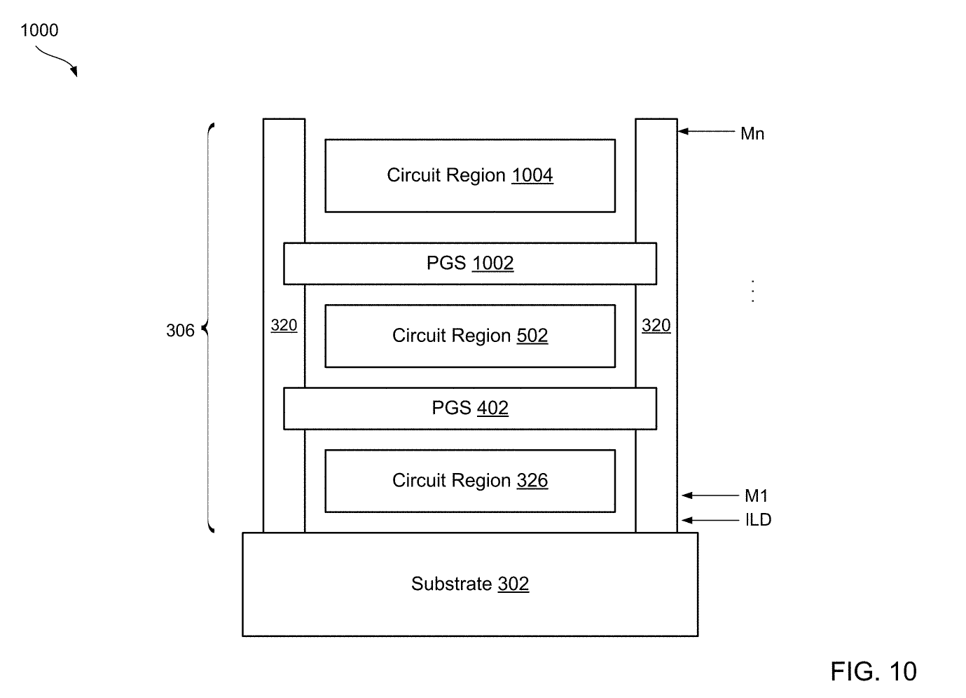

Referring to FIG. 10, in some embodiments, three or more circuit regions may be isolated from each other using a plurality of patterned ground shields and an isolation wall coupled to the plurality of patterned ground shields. In the example of FIG. 10, a device 1000 includes an interconnect structure 306 including a plurality of vertically stacked conductive layers disposed over a substrate 302. The interconnect structure 306 includes circuit regions 326, 502, and 1004. Each of the circuit regions 326, 502, and 1004 may be implemented in one or more conductive layers, and may include one or more devices including for example, transistors, diodes, capacitors, resistors, transformers, transmission lines, any other suitable devices, and/or a combination thereof.

In the example of FIG. 10, shielding planes 402 and 1002 (also referred to as patterned ground shields 402 and 1002) are disposed between the circuit regions 326, 502, and 1004. Specifically, patterned ground shield 402 is disposed in one or more conductive layers between the circuit regions 326 and 502. Patterned ground shield 1002 is disposed in one or more conductive layers between the circuit regions 502 and 1004. In various embodiments, the design (e.g., conductive material, size, shape, pattern) of the patterned ground shields 402 and 1002 may be determined based on the circuit design of the circuit regions 326, 502, and 1004. In some embodiments, patterned ground shields 402 and 1002 are substantially the same. In some embodiments, patterned ground shield 402 and the patterned ground shield 1002 include different conductive materials with different conductivities, and/or have different sizes, shapes, and/or patterns.

The interconnect structure 306 includes an isolation wall 320 including a conductive material disposed in ILD and conductive layers M1, M2, . . . , Mn stacked vertically over the substrate 302, where n is a positive integer. The isolation wall 320 may be coupled to patterned ground shields 402 and 1002, for example, by coupling to ends of fingers of the patterned ground shields 402 and 1002. In some embodiments, the isolation wall 320 may include a conductive material that is the same as the conductive material of the patterned ground shield 402 or the conductive material of the patterned ground shield 1002. In some embodiments, the isolation wall 320 may include a conductive material different from the conductive material of the patterned ground shields 402 and 1002. In some embodiments, portions of the isolation wall 320 in ILD layer and conductive layers M1, M2, M3, . . . , Mn include the same conductive material. Alternatively, in some embodiments, two or more portions of the isolation wall 320 in ILD layer and conductive layers M1, M2, M3, . . . , Mn have different conductive materials. The isolation wall 320 may surround the circuit regions 326, 502, 1004, and the patterned ground shields 402 and 1002.

The patterned ground shields 402 and 1002 and the isolation wall 320 may isolate the electric field generated by devices in a particular circuit region from other devices disposed above and/or below that particular circuit region. For example, electric field generated by devices in circuit region 326 is isolated from devices in circuit regions 502 and 1004. For further example, electric field generated by devices in circuit region 502 is isolated from devices in circuit regions 326 and 1004 and devices in the substrate 302. For example, electric field generated by devices in circuit region 1004 is isolated from devices in circuit regions 326 and 502 and devices in the substrate 302.

In some embodiments, different devices may be disposed in the circuit regions 326, 502, and 1004. In some examples, different types of capacitors may be disposed in different circuit regions. For example, decoupling capacitors (e.g., implemented using front end layers or bottom-most metal layers of the interconnect structure) may be disposed in circuit region 326 underneath the patterned ground shield 402, and finger capacitors (e.g., implemented using middle metal layers of the interconnect structure) may be disposed in circuit region 502 between the pattern ground shields 402 and 1002. In that example, the decoupling capacitors in circuit region 326 and the finger capacitors are isolated using the pattern ground shields 402 and 1002 and the isolation wall 320. In some examples, an inductor is disposed in the circuit region 502, and devices may be disposed in a circuit region over the inductor (e.g., circuit region 1004) and a circuit region under the inductor (e.g., circuit region 326).

It is noted that various configurations (e.g., configurations of isolation walls, patterned ground shields, circuit regions, interconnect structures) illustrated in FIGS. 3A, 3B, 4A, 4B, 5A, 5B, 6A, 6B, 7, 8, 9, and 10 are exemplary only and not intended to be limiting beyond what is specifically recited in the claims that follow. It will be understood by those skilled in that art that other configurations may be used.

Various advantages may be present in various applications of the present disclosure. No particular advantage is required for all embodiments, and different embodiments may offer different advantages. An advantage of some embodiments is that by using a shielding structure including a shielding plane coupled with an isolation wall in an interconnect structure, electrical interaction between devices are shielded. As such, the interconnect structure may include vertically stacked circuits without degrading the performances of the circuits. In an example, devices may be placed between the substrate and the shielding plane implemented in an intermediate conductive layer of the interconnect structure with little impact on an inductor disposed over the shielding plane. This may dramatically save chip area by utilizing the space between the substrate and the inductor, and lower power consumption. Another advantage of some embodiments is that the shielding plane includes patterns designed based on the devices placed over and/or underneath the shielding plane. Such shielding plane may effectively reduce eddy current, and isolate electrical interactions between devices disposed on opposite sides of the shielding plane. Yet another advantage of some embodiments is that the shielding plane, the isolation wall, and/or the circuits placed in the interconnect structure may satisfy a metal density requirement, thereby eliminating the need for dummy conductive features in the interconnect structure.

Although particular embodiments have been shown and described, it will be understood that it is not intended to limit the claimed inventions to the preferred embodiments, and it will be obvious to those skilled in the art that various changes and modifications may be made without department from the spirit and scope of the claimed inventions. The specification and drawings are, accordingly, to be regarded in an illustrative rather than restrictive sense. The claimed inventions are intended to cover alternatives, modifications, and equivalents.

1. A semiconductor device comprising:
an interconnect structure disposed over a semiconductor substrate, wherein the interconnect structure includes:
a first device disposed in a first portion of the interconnect structure, wherein the first device is a passive circuit element;
a first shielding plane including a first conductive material disposed in a second portion of the interconnect structure over the first portion of the interconnect structure, the first shielding plane formed in a metal layer immediately above a metal layer of the first device;
a second device disposed in a third portion of the interconnect structure over the second portion of the interconnect structure, the second device comprising an inductive coil, wherein at least one metal layer separates the second device from the first shielding plane; and
an isolation wall including a second conductive material disposed in the first, second, and third portions of the interconnect structure, wherein the isolation wall is coupled to the first shielding plane, wherein the isolation wall physically contacts a P-type diffusion material formed in a top surface of the substrate and extends above the second device, the isolation wall laterally surrounds the first device, the first shielding plane, and the second device.

2. The semiconductor device of claim 1, wherein the first conductive material and the second conductive material are different.

3. (canceled)

4. The semiconductor device of claim 1, wherein the inductor includes a coil of a third conductive material different from the first and second conductive materials.

5. The semiconductor device of claim 1, wherein the first device is disposed in a first conductive layer,
wherein the first shielding plane is disposed in a second conductive layer over the first conductive layer; and
wherein the second conductive layer is adjacent to the first conductive layer.

6. The semiconductor device of claim 1, wherein the first shielding plane is disposed in a first conductive layer;
wherein the second device is disposed in a second conductive layer over the first conductive layer; and
wherein the second conductive layer is adjacent to the first conductive layer.

7. The semiconductor device of claim 1, wherein the interconnect structure does not include a dummy conductive feature.

8. The semiconductor device of claim 1, wherein the first shielding plane includes a plurality of fingers, and
wherein the isolation wall is coupled to one end of each finger.

9. The semiconductor device of claim 1, wherein the interconnect structure includes:
a second shielding plane including a third conductive material disposed in a fourth portion of the interconnect structure over the third portion of the interconnect structure; and
a third device disposed in a fifth portion of the interconnect structure over the fourth portion of the interconnect structure.

10. The semiconductor device of claim 9, wherein the isolation wall surrounds the second shielding plane and the third device.

11. A method of fabricating a semiconductor device, comprising:
forming an interconnect structure disposed over a semiconductor substrate, wherein the forming the interconnect structure includes:
forming a first device in a first portion of the interconnect structure, the first device comprising a last metal layer of the interconnect structure, wherein the first device is a passive circuit element; and
forming a first shielding plane including a first conductive material in a second portion of the interconnect structure over the first portion of the interconnect structure, the first shielding plane formed in a next metal layer above the last metal layer of the interconnect structure;
forming a second device in a third portion of the interconnect structure over the second portion of the interconnect structure, the second device comprising an inductive coil, wherein at least one metal layer separates the second device from the first shielding plane; and
forming an isolation wall including a second conductive material in the first, second, and third portions of the interconnect structure, wherein the isolation wall is coupled to the first shielding plane, and wherein the isolation wall surrounds the first device, the first shielding plane, and the second device.

12. The method of claim 11, wherein the first conductive material and the second conductive material are different.

13. (canceled)

14. The method of claim 11, wherein the inductor includes a coil of a third conductive material different from the second conductive material.

15. The method of claim 11, wherein the first device is disposed in a first conductive layer,
wherein the first shielding plane is disposed in a second conductive layer over the first conductive layer; and
wherein the second conductive layer is adjacent to the first conductive layer.

16. The method of claim 11, wherein the first shielding plane is disposed in a first conductive layer;
wherein the second device is disposed in a second conductive layer over the first conductive layer; and
wherein the second conductive layer is adjacent to the first conductive layer.

17. The method of claim 11, wherein the interconnect structure does not include a dummy conductive feature.

18. The method of claim 11, wherein the first shielding plane includes a plurality of fingers, and
wherein the isolation wall is coupled to one end of each finger.

19. The method of claim 11, wherein the interconnect structure includes:
a second shielding plane including a third conductive material disposed in a fourth portion of the interconnect structure over the third portion of the interconnect structure; and
a third device disposed in a fifth portion of the interconnect structure over the fourth portion of the interconnect structure

20. The method of claim 19, wherein the isolation wall surrounds the second shielding plane and the third device.

21. The semiconductor device of claim 1, wherein the isolation wall further comprises:
a first portion disposed below the first shielding plane in the first portion of the interconnect structure and laterally circumscribing the first device; and
a second portion disposed above the first shielding plane in the third portion of the interconnect structure and laterally circumscribing the second device.

22. The method of claim 11, wherein the isolation wall further comprises:
a first portion disposed below the first shielding plane in the first portion of the interconnect structure and laterally circumscribing the first device; and
a second portion disposed above the first shielding plane in the third portion of the interconnect structure and laterally circumscribing the second device.

23. The semiconductor device of claim 1, wherein a portion of the first device is closer to the isolation wall than the inductive coil.

24. The method of claim 11, wherein a portion of the first device is closer to the isolation wall than the inductive coil.
